(19) United States
(12) Patent Application Publication
(10) Pub. No.: US 2026/0139375 A1
(43) Pub. Date: May 21, 2026

(54) POWDER MITIGATION AND EXHAUST MANAGEMENT FOR THIN FILM DEPOSITION

(71) Applicant: NFINITE NANOTECHNOLOGY INC., Waterloo (CA)

(72) Inventors: Jhi Yong Loke, Waterloo (CA); Chee Hau TEOH, Kitchener (CA); Kevin MUSSELMAN, Waterloo (CA); Janarthanan Ganesh SELVARAJ, Waterloo (CA)

(73) Assignee: NFINITE NANOTECHNOLOGY INC., Waterloo, ON (CA)

(21) Appl. No.: 19/118,641

(22) PCT Filed: Oct. 5, 2023
(86) PCT No.: PCT/IB2023/060024

§ 371 Date: Apr. 4, 2025

Related U.S. Application Data
(60) Provisional application No. 63/413,440, filed on Oct. 5, 2022.

(51) Int. Cl. C23C 16/455; C23C 16/44; C23C 16/448; C23C 22/27; C23C 22/77

(52) U.S. Cl. CPC C23C 16/45555; C23C 16/4408; C23C 16/448; C23C 16/45519; C23C 16/45551; C23C 22/27; C23C 22/77

(57) ABSTRACT

A spatial atomic layer deposition (SALD) system includes a coating head with an arrangement of channels including a precursor gas channel, a reactant gas channel, and inert gas and exhaust channels to assist in purging a target substrate of unwanted material, such as powder, contaminates, or dust, at or near the location of deposition. The coating head may also include a surface 2024/075062 treatment apparatus, a particulate monitoring device, an ultrasonic vibrator, a heater, a dehumidifier, or a static charge generator to assist with purging the substrate. Various channels and auxiliary devices may be provided as modules. Surface treatment may be provided to the body of the coating head adjacent the substrate. Exhaust flow paths outside the coating head, an environmental control chamber for the coating head, and output slit offsets may also be provided.

### FIELD

The present disclosure relates generally to gas control systems and more specifically to gas control for thin film deposition.

### BACKGROUND

Spatial atomic layer deposition (SALD) is an open-air vapor-phase deposition technique. A coating head is typically used to deliver one or more chemical precursors that react with other chemical precursors and/or decompose due to an external energy source (e.g., thermal, laser, plasma), resulting in the deposition of a desired material on a surface. A variety of gas channels may be present, including those to deliver the chemical precursors, shielding gas(es), energy sources, and/or exhaust channels to remove reaction products, as illustrated in FIG. 1. A substrate 102 may be moved relative to a coating head 100, such as in one direction or in oscillation. As for gas delivery and exhaust, “i” represents inert gas, “a” represents a precursor chemical gas, “b” represents a reactant, and “e” represents exhaust.

Systems such as that depicted in FIG. 1 can generate powder that causes issues such as clogging. Chemical precursors may cause undesired reactions when they mix with atmospheric air and lead to spatial and temporal non-uniformities in the deposited material or coating. Precursors and/or reactant gases may interact with each other or other gasses outside of intended circumstances leading to undesirable reaction products. It is a challenge in the industry to maintain sufficient gas isolation to ensure that the coating can be properly deposited onto substrates without being affected by surrounding air and/or other gas(es) found in the process and/or apparatus. The clogging issue, reaction with atmospheric air, insufficient gas isolation, and unexpected reaction products may affect process control and often lead to poor coating properties such as non-uniform deposition, formation of pinholes and inconsistent performance. Hence, balancing the flow interaction among the chemical precursor, the shielding gas(es) and exhaust strength is effective in reducing powder formation.

### SUMMARY

According to an aspect of the present disclosure, a SALD system includes a coating head including a precursor gas channel configured to provide a precursor gas to a substrate, a reactant gas channel positioned forward of the precursor gas channel, where the reactant gas channel is configured to provide a reactant gas to the substrate, and a sequence of inert gas channels positioned with respect to the precursor gas channel and the reactant gas channel. Each inert gas channel is configured to provide an inert gas to the substrate to purge unwanted material from the substrate.

The sequence of inert gas channels may be positioned forward or rearward of the reactant gas channel and the precursor gas channel.

The sequence of inert gas channels may be positioned between the reactant gas channel and the precursor gas channel.

The SALD system may further include a body in which the precursor gas channel and the reactant gas channel are provided and a module in which the sequence of inert gas channels is provided. The module may be removably attachable to the body.

The SALD system may further include, attached to the coating head, a surface treatment apparatus, a particulate monitoring device, an ultrasonic vibrator, a heater, a dehumidifier, a static charge generator, or a combination of such.

The coating head may further include a surface treatment at surface of the body of the coating head adjacent the substrate.

The surface treatment may include a layer of octadecyl phosphonic acid.

The SALD system may further include a first exhaust flow path connected to an exhaust channel of the coating head adjacent the precursor gas channel and a second exhaust flow path connected to another exhaust channel of the coating head adjacent the reactant gas channel.

The SALD system may further include a pressure gauge positioned at the first exhaust flow path or the second exhaust flow path. The pressure gauge may be configured to detect a blockage in the first exhaust flow path or the second exhaust flow path.

The SALD system may further include a pump positioned at the first exhaust flow path or the second exhaust flow path and a flow speed controller connected to the pump. The pump and flow speed controller may be configured to increase a flow rate of exhaust through the first exhaust flow path or the second exhaust flow path to clear a blockage.

The SALD system may further include an environmental control chamber in which the coating head is positioned. The environmental control chamber may be configured to control temperature, pressure, and humidity of a local environment around the coating head.

An end slit of the precursor gas channel or the reactant gas channel may be offset from an end slit of an inert gas channel in a direction away from the substrate.

According to another aspect of the present disclosure, a SALD system includes a coating head including a precursor gas channel configured to provide a precursor gas to a substrate, a reactant gas channel positioned forward of the precursor gas channel, where the reactant gas channel configured to provide a reactant gas to the substrate, and a sequence of exhaust channels positioned with respect to the precursor gas channel and the reactant gas channel. Each exhaust channel is configured to withdraw unwanted material from a vicinity of the substrate.

The sequence of inert gas channels may be positioned forward or rearward of the reactant gas channel and the precursor gas channel.

The SALD system may further include a body in which the precursor gas channel and the reactant gas channel are provided and a module in which the sequence of exhaust channels is provided. The module is removably attachable to the body.

The SALD system may further include, attached to the coating head, a surface treatment apparatus, a particulate monitoring device, an ultrasonic vibrator, a heater, a dehumidifier, a static charge generator, or a combination of such.

The coating head further may further include a surface treatment at surface of the body of the coating head adjacent the substrate.

The surface treatment may include a layer of octadecyl phosphonic acid.

The SALD system may further include a first exhaust flow path connected to an exhaust channel of the coating head adjacent the precursor gas channel and a second exhaust flow path connected to another exhaust channel of the coating head adjacent the reactant gas channel.

The SALD system may further include a pressure gauge positioned at the first exhaust flow path or the second exhaust flow path. The pressure gauge may be configured to detect a blockage in the first exhaust flow path or the second exhaust flow path.

The SALD system may further include a pump positioned at the first exhaust flow path or the second exhaust flow path and a flow speed controller connected to the pump. The pump and flow speed controller are configured to increase a flow rate of exhaust through the first exhaust flow path or the second exhaust flow path to clear a blockage.

The SALD system may further include an environmental control chamber in which the coating head is positioned. The environmental control chamber may be configured to control temperature, pressure, and humidity of a local environment around the coating head.

An end slit of the precursor gas channel, the reactant gas channel, or an exhaust channel may be offset from an end slit of an inert gas channel in a direction away from the substrate.

According to another aspect of the present disclosure, a SALD system includes a coating head including a precursor gas channel configured to provide a precursor gas to a substrate a reactant gas channel positioned forward of the precursor gas channel, where the reactant gas channel configured to provide a reactant gas to the substrate, and an alternating sequence of inert gas channels and exhaust channels positioned with respect to the precursor gas channel and the reactant gas channel. Each inert gas channel is configured to provide an inert gas to the substrate to purge unwanted material from the substrate. Each exhaust channel is configured to withdraw unwanted material from a vicinity of the substrate.

The SALD system may further include a body in which the precursor gas channel and the reactant gas channel are provided and a module in which the alternating sequence of inert gas channels and exhaust channels is provided. The module may be removably attachable to the body.

The SALD system may further include, attached to the coating head, a surface treatment apparatus, a particulate monitoring device, an ultrasonic vibrator, a heater, a dehumidifier, a static charge generator, or a combination of such.

The coating head may further include a surface treatment at surface of the body of the coating head adjacent the substrate.

The surface treatment may include a layer of octadecyl phosphonic acid.

The SALD system may further include a first exhaust flow path connected to an exhaust channel of the coating head adjacent the precursor gas channel and a second exhaust flow path connected to another exhaust channel of the coating head adjacent the reactant gas channel.

The SALD system may further include a pressure gauge positioned at the first exhaust flow path or the second exhaust flow path. The pressure gauge may be configured to detect a blockage in the first exhaust flow path or the second exhaust flow path.

The SALD system may further include a pump positioned at the first exhaust flow path or the second exhaust flow path and a flow speed controller connected to the pump. The pump and flow speed controller may be configured to increase a flow rate of exhaust through the first exhaust flow path or the second exhaust flow path to clear a blockage.

The SALD system may further include an environmental control chamber in which the coating head is positioned. The environmental control chamber may be configured to control temperature, pressure, and humidity of a local environment around the coating head.

An end slit of the precursor gas channel, the reactant gas channel, or an exhaust channel may be offset from an end slit of an inert gas channel in a direction away from the substrate.

### BRIEF DESCRIPTION OF THE DRAWINGS

For a clear understanding of the disclosure, some embodiments of the present disclosure are illustrated as an example and are not limited to the figures of the accompanying drawings.

FIG. 1 is a diagram of a conventional spatial atomic layer deposition (SALD) process.

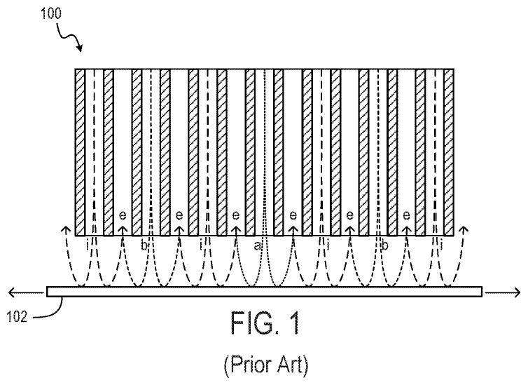

FIG. 2 is a diagram of an additional number of inert gas channels at both ends of the same coating head.

FIG. 3 is a diagram of an additional number of inert gas channels beside the exhaust channels surrounding the chemical precursor channel.

FIG. 4 is a diagram of additional modules containing inert gas channels that are assembled to both ends of the coating head.

FIG. 5 is a diagram of additional modules containing inert gas channels on one end of the coating head.

FIG. 6 is a diagram of additional modules containing exhaust channels on one end of the coating head.

FIG. 7 is a diagram of additional modules each containing either inert gas channels or exhaust channels.

FIG. 8 is a diagram of additional modules containing inert gas channels and exhaust channels arranged in an alternating sequence.

FIG. 9 is a diagram of a surface treater or a particulate monitoring device attached to one end of the coating head.

FIG. 10 is a diagram of a layer of coating growth inhibitor applied on the bottom surface of the coating head.

FIG. 11 is a diagram of a system including an arrangement of components for generating vacuum suction (for exhaust), dynamic control of vacuum strength, monitoring line clogging, trapping and filtering powder, and for line unclogging.

FIG. 12 is a diagram of parallel bypass circuits for the powder collector and particle filter.

FIG. 13 is a diagram of multiple vacuum pressure gauges and on/off valves connected to individual exhaust channels in a coating head.

FIG. 14 is a diagram of an exhaust system using a mechanical vacuum pump as the vacuum generating source instead of using venturi pumps.

FIG. 15 is a diagram of an example environmental control chamber configured to control a local deposition environment.

FIG. 16A is a diagram of an example channel offset configured to reduce interaction among gases.

FIG. 16B is a diagram of another example channel offset configured to reduce interaction among gases.

FIG. 17 is a perspective diagram of an example coating head that may implement any of the features and aspects discussed herein.

### DETAILED DESCRIPTION

In order to commercialize open-air thin-film deposition techniques for mass production, processes need to be made reliable and effective without significant downtime. Exhaust channels are typically connected to an exhaust system which includes one or multiple vacuum generating sources to remove the reaction products.

Downtime may be caused by clogs in an exhaust channel and powder build-up under the coating head.

### Airborne Contamination Management

During the deposition process, airborne particulates from the surrounding environment can contaminate the material surfaces. Conventional vacuum-based deposition techniques require a vacuum chamber to remove air particles and contaminants. Alternatively, a cleanroom can be used to provide a well-isolated and controlled environment from contamination, but such facilities are very expensive to maintain and operate.

Conventional close-proximity SALD techniques include air-bearing (air-cushioning) designs with a nitrogen environment between the substrate and reactor which may help with contaminant control. However, balancing air-bearing for precise gap and movement control is challenging and it also limits the type of substrate, especially its weights and geometries, that can be processed.

Disclosed herein are open-air deposition processes that may operate with or without a vacuum chamber or cleanroom, depending on the application. The reactor has continuous streams of inert gas(es) to purge airborne contamination and control the surface quality prior to deposition. The pressure and flow rates of the streams of inert gas(es) as well as exhaust can be actively controlled to isolate the deposition area under the coating head; by creating a sufficient outflow of inert gas(es) from the deposition area, inflow of surrounding air and contaminants is prevented. A particulate monitor may be installed to determine the particulate level near the deposition area. An air purifier may be used to reduce dust levels. These components create an isolated environment for coating reactions to occur on the substrate surface and keep contaminants out of the deposition area.

### Substrate Surface Treatment and Cleanliness

Surface cleanliness is important to ensure the quality of the coating, such as consistency, uniformity, pinhole-free, adhesion, etc.

Apart from surface cleanliness, different substrate materials have different surface chemistries which affect the properties of the coating such as, but not limited to adhesion, morphology, density, and crystallinity.

Also disclosed herein are cleaning methods, using several purge and exhaust steps, which may be used prior to the deposition process to improve surface cleanliness.

Surface treatment such as, but not limited to, corona, plasma, and dielectric barrier discharge, can be used to prime the substrate surface to enhance the coating process and coating properties. It was discovered that ozone and plasma treatment will improve the surface chemistry of some substrates, such as polyethylene, for better coating quality that improves barrier performance. Plasma ALD may be used to coat materials with challenging surface chemistry.

### Precursor Gas Isolation

The precursor gas(es) may be highly reactive (e.g., pyrophoric). They may react instantly when exposed to air or another reactant. Hence, it may be imperative to prevent the precursors gas(es) from mixing and reacting inadvertently with each other or air, especially in the open-air process. During conventional atomic layer deposition (ALD) process, the precursor gas(es) are introduced one gas at a time in a vacuum chamber to prevent them, from mixing. This makes conventional ALD slow and difficult to scale up.

Instead of introducing the precursor gas(es) at different times, the techniques disclosed herein introduce gases at the same time and separate them spatially. Streams of inert gas(es) separate the precursor gas from mixing with either the surrounding air or the neighboring reactant gas(es). Despite the presence of streams of inert gas(es) on either side of the precursor channels, the relative motion of the substrate and coating head can result in air passing through these streams. Purging before and after the deposition area with one or more streams of inert gas(es) and one or more exhaust channels may be used to reduce the amount of surrounding air that is drawn into the deposition area.

### Coating Head and Channel Powder Mitigation

A variety of factors, including, but not limited to, excessive chemical precursor gas(es), poorly isolated precursor gas(es), or airborne contamination may cause powder formation which may accumulate in various parts of the system, including under the coating head or in the exhaust channel. Powder build-up under the coating head may cause non-uniformity in the coating, may alter the properties of the resulting coating, or may partially or completely block gas output slits. Such powder may also contaminate surface cleanliness of the substrate and/or coating. On the other hand, powder build-up inside one or more channels may lead to clogging and affect the exhaust effectiveness and the deposition process. A precursor may also diffuse at the bottom face of the coating head made of plastic or similar material, which may cause clogging particularly at the channel output slits resulting in maintenance downtime to clear.

The techniques disclosed herein use various approaches to address powder build-up and maintain cleanliness of the coating head, such as reducing powder formation, redirecting an accumulation area, and using high suction.

To reduce powder formation, a gas isolation system may be used to prevent the reaction of a chemical precursor with the surrounding air or neighboring precursors.

To prevent powder formation, a film-growth inhibitor may be applied to the surfaces of the apparatus (e.g., the bottom face of the coating head). This may include, for example, self-assembled monolayer chemicals that prevent the attachment of the chemical precursor molecules to the surface.

To monitor powder formation, pressure of the exhaust channel(s) may be monitored. The pressure of exhaust channel(s) increases when clogs build up and at certain pressure, suction will not be effective. Pressure and flow sensors may be integrated into the system to monitor powder buildup.

To address powder formation, inert gas(es) may be introduced into the exhaust channels to redirect the powder formation further downstream of the exhaust system.

High suction pressure from the exhaust system may also be used to remove powder buildup from the deposition area.

### Excess Reactant Management

Excess chemical precursors that do not react on the substrate surface may cause unwanted chemical vapor deposition (CVD) reactions, leading to non-uniform coatings. They may also cause powder buildup and reduce precursor utilization. Powder buildup may clog system components including gas channels, manifolds, and filters and render them ineffective.

Deposition, as disclosed herein, is a self-limiting process and different sets of optimal deposition conditions for different materials are determined to reduce the amount of excess reactants. Excess reactants get removed through the exhaust channels within the coating head, which are connected to exhaust filters and exhaust pumps and monitored by one or more flow monitors. The exhaust filter may be a replacement filter with a large volume to collect powder and reduce buildup. The exhaust pump may be controlled to maintain exhaust flow rate at the desired level.

There may be two or more exhaust lines and it may be possible to switch the exhaust operation between the lines, so that a particular exhaust line may undergo maintenance and service while the system remains in operation.

### EXAMPLE EMBODIMENTS

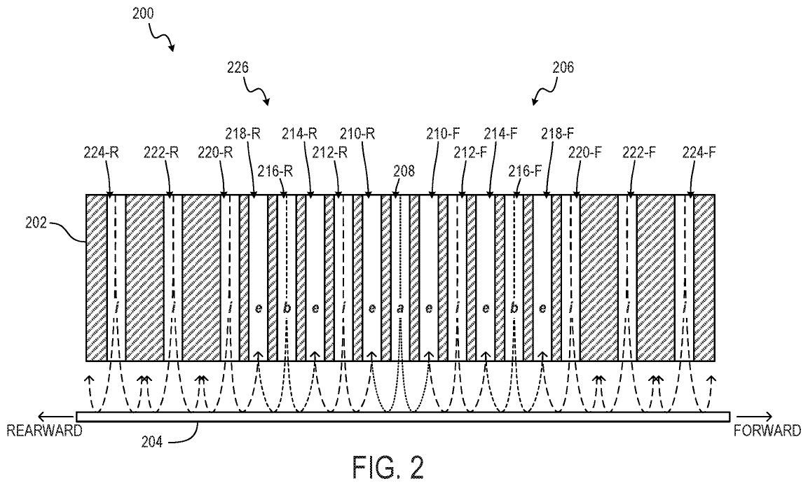

With reference to FIG. 2, an example coating head 200 includes a body 202 with an arrangement of gas channels 206 configured to deposit a coating to a substrate 204. Throughout this disclosure, “i” represents an inert gas, “a” represents a precursor chemical gas, “b” represents a reactant, and “e” represents exhaust.

The arrangement of channels 206 includes a precursor gas channel 208 and further channels in a forward direction as follows (from nearest to furthest): exhaust channel 210-F, inert gas channel 212-F, exhaust channel 214-F, reactant gas channel 216-F, exhaust channel 218-F, and a sequence of inert gas channels 220-F, 222-F, 224-F (e.g., three of such). As the substrate 204 moves forward relative to the coating head 200, at a given point on the substrate 204, the precursor gas channel 208 deposits precursor gas, the excess of which (or excess products, powder, impurities, etc.) is then exhausted via exhaust channels 210-F, 214-F with the help of inert gas delivered by the inert gas channel 212-F, before the reactant gas channel 216-F delivers reactant gas.

Subsequently, the excess of which (or excess products, powder, impurities, etc.) is purged by inert gas delivered by the sequence of inert gas channels 220-F, 222-F, 224-F.

The inert gas channels 220-F, 222-F, 224-F are arranged one after the other so that the substrate 204 passes the channels in sequence. Any suitable number of inert gas channels 220-F, 222-F, 224-F, such as three, four, five, or more, may be provided. The sequential introduction of inert gas to a given point on the substate 204 and the turbulence created by such provides for effective removal of undesirable solids, gases, and other materials.

In various examples, it may be useful to provide a complementary arrangement of channels 226 extending in the rearward direction. The complementary arrangement of channels 226 is designated by the same reference numbers as the arrangement of channels 206 with “R” instead of “F”. The complementary arrangement of channels 226 may function in the same manner but in opposite direction as the arrangement of channels 206. Various channels in the arrangements 206, 226 may be activated and deactivated, depending on the movement direction of the substrate 204, to facilitate various modes of deposition.

It should be noted that, throughout this disclosure, directional terms, such as forward and rearward, are not to be considered absolute or unduly limiting. Rather, these terms are relative and merely illustrate that different directions of arrangement and motion are possible.

When the substrate 204 is moved forward relative to the coating head 200, the endmost rearward inert gas channels 220-R, 222-R, 224-R provide streams of inert gas to purge particulates, dust, or impurities before a given point of the substrate 204 enters the deposition area that begins under the precursor channel 208 and continues under channels 210-F-218-F. Channels 212-R-218-R, if provided, may be inactive at this time. Endmost inert gas channels 220-F, 222-F, 224-F provide additional streams of inert gas after deposition for further purging.

When the substrate 204 is moved rearward relative to the coating head 200, if such functionality is provided, a similar process occurs as discussed above with the operation of forward (“-F”) and rearward (“-R”) channels being swapped.

In the coating head 200 and in the other coating heads discussed herein, the channels are elongate channels that extend along the width of the coating head, and a corresponding complete or partial width of the substrate 204, and end at slits through which gas is outputted to the substrate 204. Examples of such coating heads and supporting systems are discussed in US published patent application US 2022/0243326, which is incorporated herein by reference.

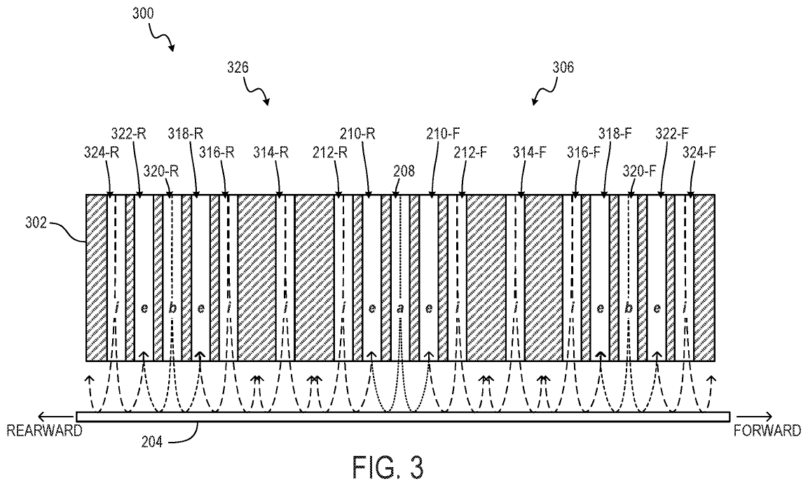

With reference to FIG. 3, an example coating head 300 includes a body 302 with an arrangement of gas channels 306 configured to deposit a coating to a substrate 204. In this example, additional streams of inert gas are placed beside exhaust channels that are surrounding a channel delivering the chemical precursor gas. Powder formation may occur in the deposition area when the chemical precursor reacts with a reactant gas or air in the environment before impinging on the substrate 204. The additional streams of inert gas may reduce the likelihood of the chemical precursor gas of undesirably interacting with the reactant or environmental air, reducing the powder formation and improving powder management during the deposition process.

The arrangement of channels 306 includes a precursor gas channel 208 and further channels in a forward direction as follows (from nearest to furthest): exhaust channel 210-F, inert gas channel 212-F, inert gas channel 314-F, inert gas channel 316-F, exhaust channel 318-F, reactant gas channel 320-F, exhaust channel 322-F, and an inert gas channel 324-F. The sequence of inert gas channels 212-F, 314-F, 316-F is positioned between the precursor gas channel 208 and the reactant gas channel 320-F.

As the substrate 204 moves forward relative to the coating head 300, at a given point on the substrate 204, the precursor gas channel 208 deposits precursor gas, the excess of which (or excess products, powder, impurities, etc.) is then exhausted via exhaust channel 210-F. The sequence of inert gas channels 212-F, 314-F, 316-F purges, before the reactant gas channel 320-F delivers reactant gas, which is assisted by exhaust channels 318-F, 322-F. A final purge is provided by inert gas channel 324-F.

The sequence of inert gas channels 212-F, 314-F, 316-F are arranged one after the other so that the substrate 204 passes the channels in sequence. Any suitable number of inert gas channels 212-F, 314-F, 316-F, such as three, four, five, or more, may be provided. The sequential introduction of inert gas to a given point on the substate 204 and the turbulence created by such provides for effective removal of undesirable solids, gases, and other materials.

In further examples, additional exhaust channels (not shown) may be provided between inert gas channels 212-F, 314-F, 316-F in the sequence.

In various examples, it may be useful to provide a complementary arrangement of channels 326 extending in the rearward direction. The complementary arrangement of channels 326 is designated by the same reference numbers as the arrangement of channels 306 with “R” instead of “F”. The complementary arrangement of channels 326 may function in the same manner but in opposite direction as the arrangement of channels 306. Various channels in the arrangements 306, 326 may be activated and deactivated, depending on the movement direction of the substrate 204, to facilitate various modes of deposition.

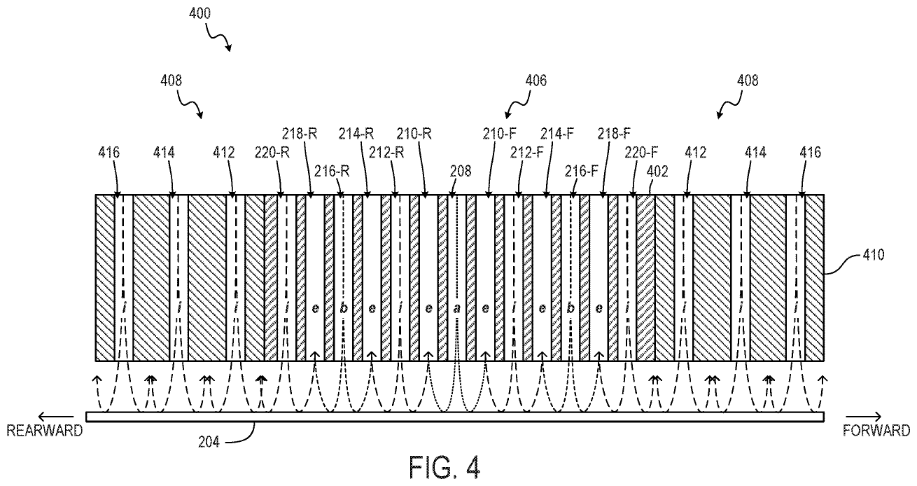

With reference to FIG. 4, an example coating head 400 includes a body 402 with an arrangement of gas channels 406 configured to deposit a coating to a substrate 204. The arrangement of gas channels 406 may be similar to the arrangements 206, 226 discussed above, and FIG. 2 and related description may be referenced for details not repeated here.

A module 408 that includes a body 410 with a sequence of inert gas channels 412, 414, 416 may be attached to the body 402 of the coating head 400 at a forward side, rearward side, or both sides. The module 408 allows for various useful configurations of additional inert gas channels to provide purging as needed for specific implementations.

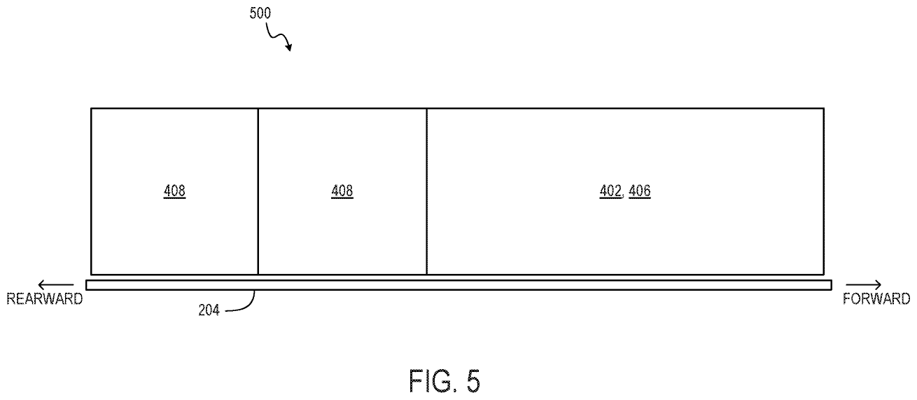

The module 408 may include any suitable number of inert gas channels 412, 414, 416. Any suitable number of modules 408 may be attached to the body 402 of the coating head 400. FIG. 5 shows an example coating head 500 with several modules 408 installed on the same side of a body 402 that provides an arrangement 406 of precursor, reactant, and exhaust channels (detail omitted from figure for sake of clarity). Numerous other examples are possible with such modularity.

The module 408 may be removably attached to the body 402 of the coating head 400 using bolts, a clamp, or similar fastener.

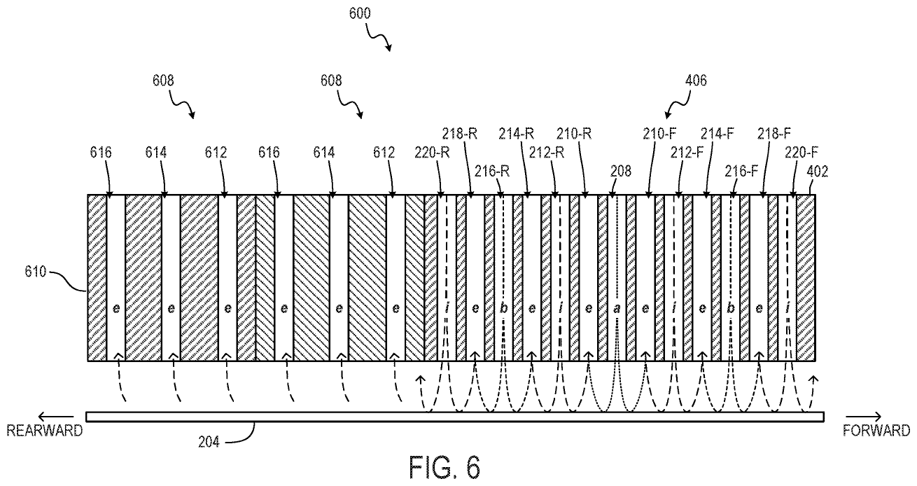

With reference to FIG. 6, an example coating head 600 includes a body 402 with an arrangement of gas channels 406 configured to deposit a coating to a substrate 204. The arrangement of gas channels 406 may be similar to the arrangements 206, 226 discussed above, and FIG. 2 and related description may be referenced for details not repeated here.

A module 608 that includes a body 610 with a sequence of exhaust channels 612, 614, 616 may be attached to the body 402 of the coating head 600 at a forward side, rearward side, or both sides. The module 608 allows for various useful configurations of additional exhaust channels to provide withdrawal of material, such as airborne particulates, from the vicinity of the substrate 204, as needed for specific implementations.

The module 608 may include any suitable number of exhaust channels 612, 614, 616. Any suitable number of modules 608 may be attached to the body 402 of the coating head 600. The module 608 may be removably attached to the body 402 using bolts, a clamp, or similar fastener.

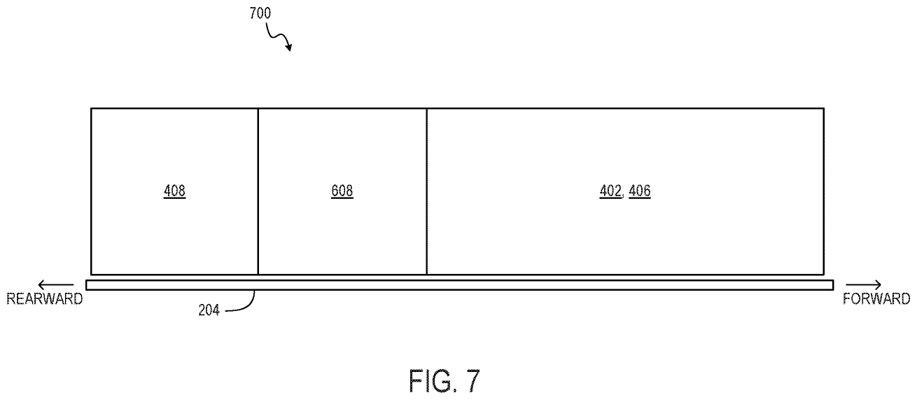

As shown in FIG. 7, a coating head 700 may be provided with an inert-gas module 408 having inert gas channels combined with an exhaust module 608 having exhaust channels. Any suitable number and configuration of modules 408, 608 may be used, as needed by particular implementation requirements. Modules 408, 608 may be arranged in an alternating sequence. Inert gas may be provided to the module 408 to dislodge particulates from the substrate 204. A vacuum source may be provided to the module 608 to remove the dislodged particulates.

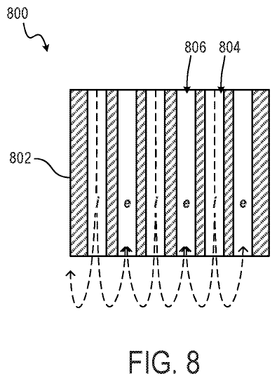

FIG. 8 shows another example module 800 including a body 802 that includes an alternating sequence of inert gas channels 804 and exhaust channels 806. Similar to the modules 408, 608, the module 800 may be attached at one or both ends of a body of a coating head using bolts, a clamp, or similar fastener. Any suitable number of modules 800 may be used. A module 800 may be combined with an inert-gas module 408 and/or exhaust module 608.

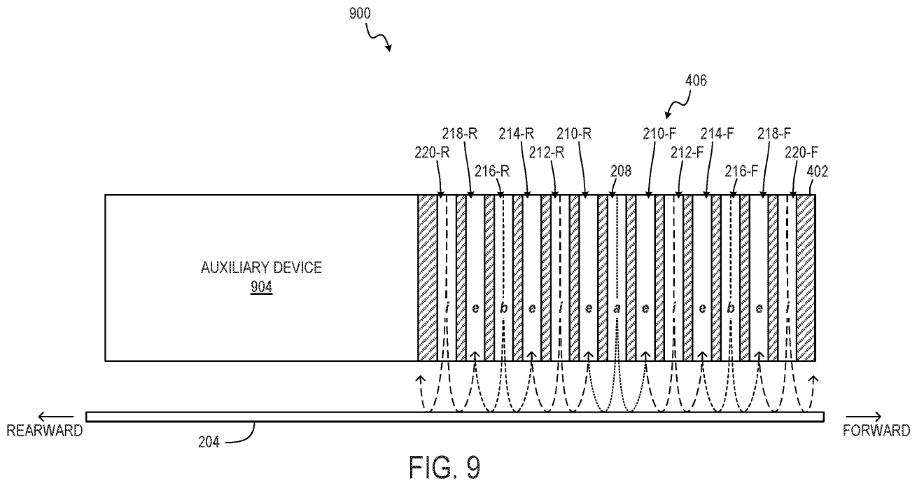

With reference to FIG. 9, an example coating head 900 includes a body 402 with an arrangement of gas channels 406 configured to deposit a coating to a substrate 204. The arrangement of gas channels 406 may be similar to the arrangements 206, 226 discussed above, and FIG. 2 and related description may be referenced for details not repeated here.

The coating head 900 further includes an auxiliary device 902 attached thereto. The auxiliary device 902 may be modular and removable attachable to the body 402 or another module 408, 608, 800 using bolts, a clamp, or similar fastener. The auxiliary device 902 is configured to provide functionality to reduce or eliminate the manifestation or effects of powder and/or other undesirable materials. In various examples, the auxiliary device 902 may include a surface treatment apparatus, a particulate monitoring device, an ultrasonic vibrator, a heater, a dehumidifier, a static charge generator, or a combination of such.

Examples of a surface treatment apparatus include a corona treater, plasma treater, dielectric barrier discharge plasma source, and ozone source configured to prime the substrate 204 surface to improve coating quality and properties, such as coating adhesion to the substrate.

A particulate monitoring device may be configured to monitor surface cleanliness of the substrate upon entry to and/or exit from the deposition area. An example particulate monitoring device may include a device made by Piera Systems (e.g., PEK-7100-1), which may be useful to monitor particulates around the coating head 900 or in the wider system. Such devices allow the monitoring of an amount of particles introduced at or near the deposition area during the process for quality assurance and quality control of the environment and/or deposition process.

An ultrasonic vibrator may function to dislodge powder build up on the body 402 of the coating head 900 by vibrating at an appropriate frequency.

A heater or dehumidifier may prevent the powder formation.

A static charge generator may repel powder to prevent it from attaching to the bottom face (adjacent the substate 204) of the body 402 or the interior of the channels 208, 210-F-220-R, 210-R-220-R.

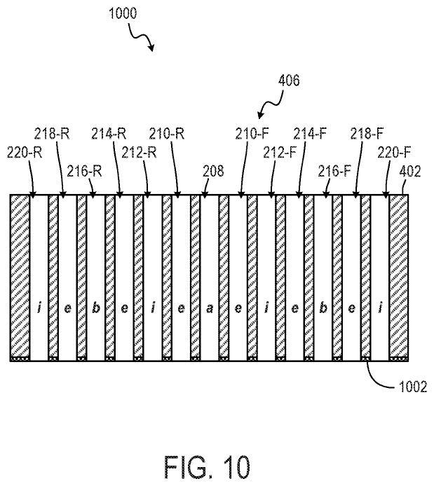

With reference to FIG. 10, an example coating head 1000 includes a body 402 with an arrangement of gas channels 406 configured to deposit a coating to a substrate 204. The arrangement of gas channels 406 may be similar to the arrangements 206, 226 discussed above, and FIG. 2 and related description may be referenced for details not repeated here.

The coating head 1000 further includes a surface treatment 1002 applied to the bottom surface (surface adjacent the substate when in use) of the body 402 of the coating head 1000. The surface treatment 1002 is configured to reduce or prevent the attachment of chemical precursor molecules to the bottom surface and/or impede powder formation on the bottom surface of the 402. The same or different surface treatment 1002 may be applied in the interior of the channels 208, 210-F-220-R, 210-R-220-R to reduce or prevent chemical precursor molecules from attaching to the walls of the channels and/or impede powder formation in the channels 208, 210-F 220-R, 210-R-220-R.

The surface treatment 1002 may include a coating growth inhibitor, a low-friction material, a sacrificial layer, or a combination of such. Examples include a coating, a deposited material, a removable plate, a removable liner, electroplating, and similar.

The surface treatment 1002 may be anhydrous or provide such property to the bottom surface of the body 402. The surface treatment 1002 may be hydrophobic. Some surface treatments 1002, such as electroplating, may incorporate multiple materials, which may have other benefits apart from reducing or preventing powder build up. For example, nickel-Teflon electroplating has the chemical resistance properties of nickel and Teflon™, the high-slip properties of Teflon, as well as the insulating properties of Teflon. As such, the properties of the bottom surface of the coating head 1000 may be tuned by selecting specific surface treatment(s) 1002, such as this electroplating example.

Examples of suitable inhibitors include poly(methyl methacrylate) or PMMA, octadecyl phosphonic acid (ODPA), dodecane thiol (DDT), and poly(vinyl pyrrolidone) or PVP. A layer of one or more of such materials may be applied, as a surface treatment 1002, to the bottom surface of the coating head 1000. ODPA was tested and found to provide useful inhibition of coating growth.

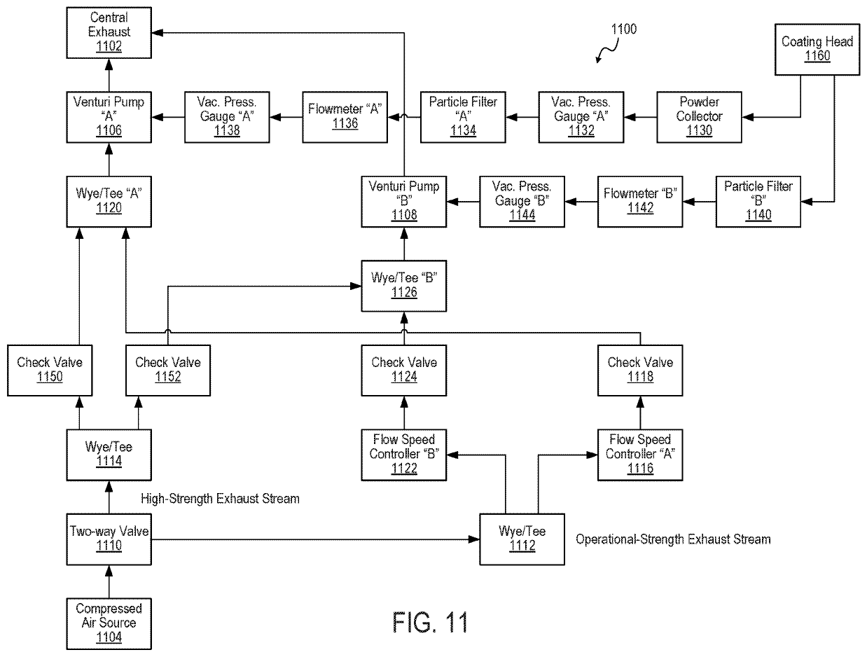

With reference to FIG. 11, an example exhaust system 1100 is configured to generate vacuum suction for exhaust channels of a coating head, such as those discussed herein, and to provide for line unclogging. The system 1100 outputs exhaust gases, powder, particulate, and reaction products to a central exhaust 1102 which may serve a larger manufacturing facility.

The exhaust system 1100 includes a compressed air source 1104 to supply pressurized air to the lines and eventually to venturi pumps 1106, 1108 to create a flow speed difference for generating a vacuum.

The exhaust system 1100 has lines (tubes, conduits, etc.) that split into two flow paths via a two-way valve 1110 connected to a first wye/tee 1112 and second wye/tee 1114, namely, an operational-strength exhaust flow path and a high-strength exhaust flow path, respectively. The lines further diverge to “A” and “B” flow paths that connect to different exhaust channels in a coating head 1160, such as any of the coating head discussed elsewhere herein. The “A” flow path includes a flow speed controller 1116, check valve 1118, wye/tee 1120, and venturi pump A 1106. The “B” flow path includes a flow speed controller 1122, check valve 1124, wye/tee 1126, and venturi pump 1108.

Exhaust channels in the coating head 1160 connect to the “A” flow path venturi pump 1106 via powder collector 1130, vacuum pressure gauge 1132, particle filter 1134, flowmeter 1136, and vacuum pressure gauge 1138.

Other exhaust channels in the coating head 1160 connect to the “B” flow path venturi pump 1108 via particle filter 1140, flowmeter 1142, and vacuum pressure gauge 1144.

In this example, the “A” flow path is connected to exhaust channels adjacent to the chemical precursor gas channel(s) in the coating head 1160. With reference to FIG. 2, for example, such exhaust channels are indicated at 210-F, 210-R. The “B” flow path is connected to the exhaust channels adjacent to the reactant channel(s) in the coating head 1160. With reference to FIG. 2, for example, such exhaust channels are indicated at 214-F, 218-F, 214-R, 218-R. Separating the exhaust into two flow paths inhibits or prevents the exhausted chemical precursor gas from reacting with the exhausted reactant gas, as may occur if a single flow path were used. This may help prevent or delay powder formation and build up in the lines, which may cause fouling and clogging.

When the two-way valve 1110 is switched to the operational strength exhaust flow path, the exhaust pressure and flow rate generated by the “A” and “B” flow path venturi pumps 1106, 1108 are tuned using the “A” and “B” flow path flow speed controllers 1116, 1122 and are optimized for balancing proper exhaust rate based on certain process conditions related to chemical precursor gas and inert shielding gas flow rates. The “A” and “B” flow path flow speed controllers 1116, 1122 may be manually or automatically tuned based on the flow requirements and using the measurement readings from the “A” and “B” flow path flowmeters 1136, 1142 as feedback. Additionally, the “A” and “B” flow path vacuum pressure gauges 1138, 1144 are used to measure the vacuum pressure generated. Dynamic control of the exhausting pressure and flow rate by tuning the flow speed controllers 1116, 1122 may ensure that the conditions throughout the deposition process are controlled and maintained over time. When there is powder build up and accumulation detected in the exhaust channels and line connections, the two-way valve 1110 may be switched to engage the high strength exhaust flow path to maximize the exhaust pressure and flow rate generated by the “A” and “B” flow path venturi pumps 1106, 1108 to remove the accumulated powder from the lines. The switching of the two-way valve 1110 may be done manually or automatically during the deposition process, in between each cycle of deposition, or when powder is starting to accumulate, for example. Check valves 1150, 1152 may be installed to prevent backflow of compressed air into wye/tees 1112, 1114 when the operational-strength exhaust flow path or high-strength exhaust flow path is engaged.

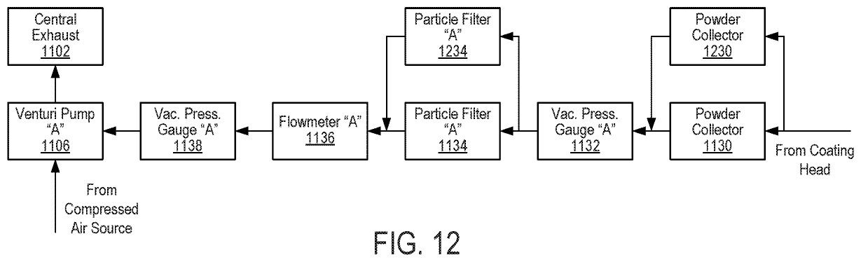

In addition to monitoring vacuum pressure generated by the venturi pumps 1106, 1108, the vacuum pressure gauges 1132, 1138, 1144 may also be used to monitor clogging in the line. For example, the two “A” flow path vacuum pressure gauges 1132, 1138 are connected to the exhaust channels (e.g., channels 210-F, 210-R of FIG. 2) adjacent to the chemical precursor gas channel(s) (e.g., channel 208 of FIG. 2) which are most sensitive to powder formation and accumulation. Clogging may occur in powder collector 1130 and particle filter 1134, which are used to trap particulates and filter out fine powders, respectively, to avoid clogging the venturi pump 1106. The vacuum pressure gauges 1132, 1138 may be used to determine where in the line the clog occurs, whether the blockage is upstream at the particle filter 1134 or downstream at the powder collector 1130. This allows an operator to quickly determine the location of clog so that maintenance is more efficient. Both the powder collector 1130 and particle filter 1134 may be fitted with bypass circuits with a second powder collector 1230 and a second particle filter 1234 in parallel, as shown in FIG. 12. The second powder collector 1230 and second particle filter 1234 may each be independently activated via respective bypass valves (not shown) which shut off flow to the respective first powder collector 1130 and first particle filter 1134. This allows for maintenance without interruption to operation. Conversely, the reactant channels usually do not deliver gas(es) would form powder in this way. Hence, multiple vacuum pressure gauges may not be required in the “B” flow path. In some examples, the “B” flow path vacuum pressure gauge 1144 may be omitted when pressure monitoring is not needed.

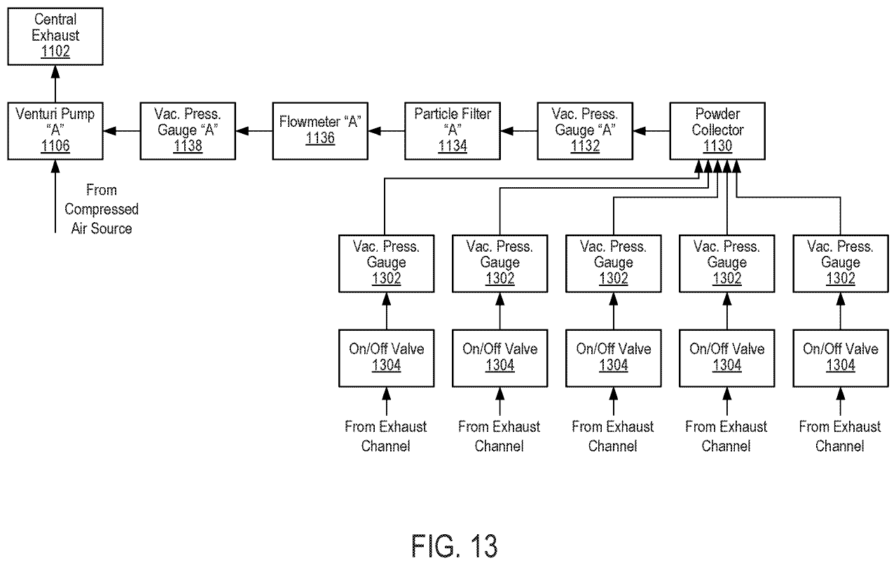

Vacuum pressure only starts to increase if a line is starting to become blocked. One example is when powder builds up around the inner walls of a tube to a point where flow is starting to be constricted. For example, the “A” flow path may be connected to two exhaust channels (e.g., channels 210-F, 210-R of FIG. 2). A potential disadvantage with this configuration is that, if one of the two tubes connected to the exhaust channels is clogged and the other is not, then flow may still pass through the tube that is not clogged. This may affect process control resulting in uncontrolled gas flows due to imbalance in exhaust flow rates at the exhaust channels, which may lead to nonuniform coating deposition and the possibility of having powder formed in the deposition area and powder settling on the substrate surface. One strategy is to fit each exhaust channel with its own venturi pump circuit, so that each of the lines connecting to the exhaust channels (e.g., channels 210-F, 210-R of FIG. 2) may be individually and independently maintained. Another strategy is to use one venturi pump 1106 and fit each line connecting to each exhaust channel with a respective vacuum pressure gauge 1302 and manual or automatic on/off valve 1304, as shown in FIG. 13, so that clogs in each line may be individually detected and cleared. The same approach shown in FIG. 13 may also be configured to use one or multiple venturi pumps when multiple coating head modules are assembled, for example.

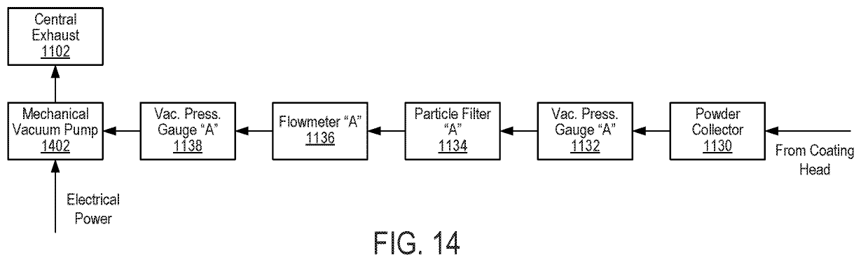

Another example exhaust system may be achieved by using one or multiple electrically driven mechanical vacuum pumps 1402 instead of a venturi pump, as shown in FIG. 14.

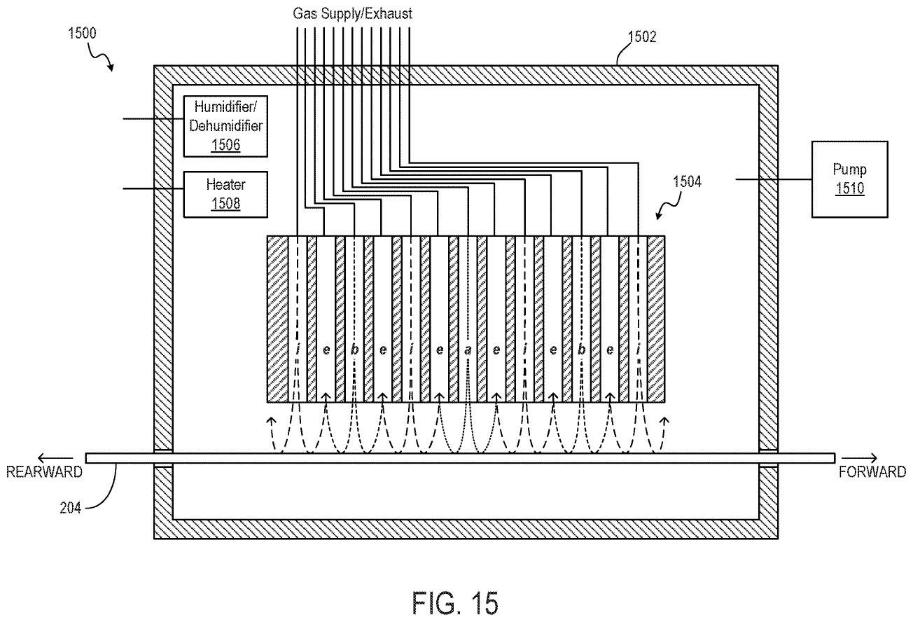

FIG. 15 shows an example system 1500 with an environmental control chamber 1502 that may be useful to regulate the local environment around a coating head 1504, such as any of the coating heads discussed elsewhere herein.

The environmental control chamber 1502 may be a box made of glass, plastic, or similar material. It may be transparent to allow its contents to be seen. The chamber 1502 may be sized to contain a coating head or heads 1504 and a portion of the substrate 204 being coated.

A humidifier/dehumidifier 1506 may be provided to the environmental control chamber 1502 to control a humidity level within the chamber 1502. The humidifier/dehumidifier 1506 may be located inside the chamber 1502 or may be located outside the chamber 1502 and communicate humidified or dehumidified gas (e.g., air) with the chamber 1502.

A heater 1508 may be provided to the environmental control chamber 1502 to control a temperature within the chamber 1502. The heater 1508 may be located inside the chamber 1502 or may be located outside the chamber 1502 and communicate warmed or cooled gas (e.g., air) with the chamber 1502.

A pump 1510 may be provided to the environmental control chamber 1502 to control a pressure level within the chamber 1502. The chamber 1502 may be controlled to have a pressure slightly higher than the greater environment (outside the chamber) to keep particulates and other undesirable material from entering the chamber 1502 and affecting the deposition process.

In other examples, the pump 1510 is configured to have the environmental control chamber 1502 at a slight negative pressure compared to the greater environment, which may improve gas delivery by the coating head 1504 to the substrate 204. A blanket of inert gas may be fed into the environmental control chamber 1502 to reduce particulates, contaminants, etc.

The humidifier/dehumidifier 1506, heater 1508, and pump 1510 may be combined as a single unit that provides conditioned air (or other gas) to the interior of the chamber 1502.

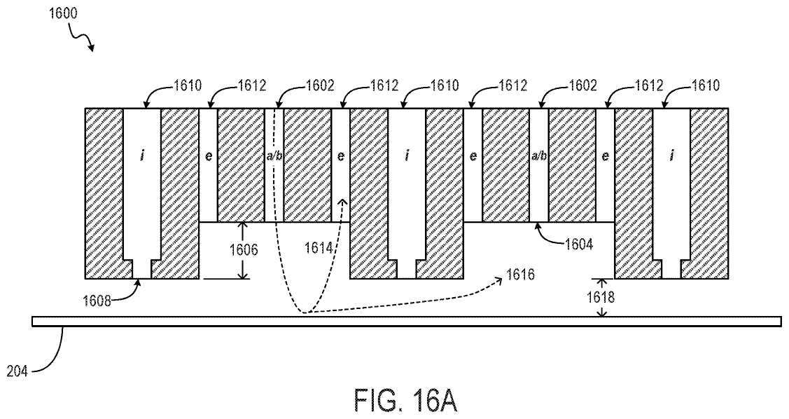

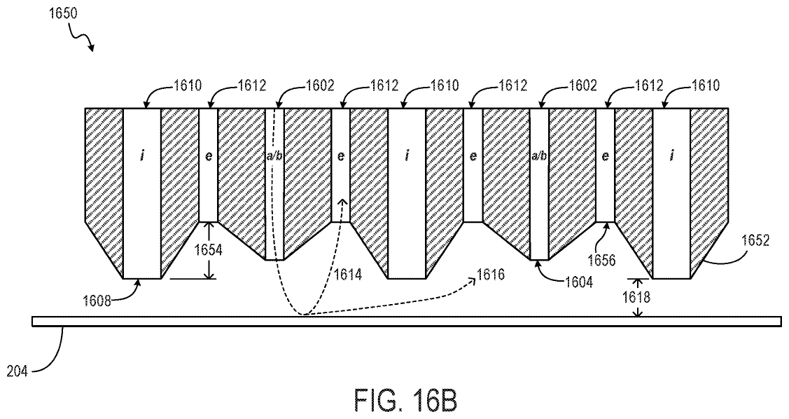

With reference to FIG. 16A, an example coating head 1600, such as any of the coating heads discussed elsewhere herein, may include channels that have slit positions that are offset to discourage unintended mixing of gas.

A precursor and/or reactant channel 1602 may have an end slit 1604 (though which gas exits to the substrate) that is offset 1606 in a direction away from the substrate 204 from an end slit 1608 of a nearby inert gas channel 1610. An exhaust channel 1612 positioned between the precursor/reactant channel 1602 and the inert gas channel 1610 may be offset in the same manner and by the same or similar amount.

This may encourage precursor/reactant gas to remain in the vicinity of the precursor and/or reactant channel 1602 and be drawn away from the substrate 204 by a nearby exhaust channel 1612 (as shown by flow path 1614), rather than leak past the inert gas channel 1610 and possibly interfere with other precursor/reactant gas (as shown by flow path 1616). That is, the reduced gap 1618 between the slit 1608 of the inert gas channel 1610 and the substate 204 may provide an obstruction sufficient to discourage unintended mixing of precursor and/or reactant gasses. Examples of suitable offsets 1606 include 0.1 mm, 0.2 mm, 0.3 mm, 0.4 mm, and 0.5 mm.

FIG. 16B, shows an example coating head 1650, such as any of the coating heads discussed elsewhere herein, that includes channels that have slit positions that are offset to discourage unintended mixing of gas. The coating head 1650 is similar to the coating head 1600 of FIG. 16A, and only differences will be discussed in detail.

The body of the coating head may be convexly beveled or curved, shown at 1652, around inert gas channels 1610 and precursor and/or reactant channels 1602. That is, the end slits 1604, 1608 of such channels 1602, 1610 may be provided at peaks. End slits 1656 of exhaust channels 1612 may be situated in respective valleys that are offset 1654 in a direction away from the substrate 204 from an end slit 1608 and/or 1604 of a nearby inert gas channel 1610 and/or precursor and/or reactant channel 1602. The reduced gap 1618 between the slit 1608 of the inert gas channel 1610 and the substate 204 may provide an obstruction sufficient to discourage unintended mixing of precursor and/or reactant gasses. Examples of suitable offsets 1654 include 0.1 mm, 0.2 mm, 0.3 mm, 0.4 mm, and 0.5 mm. In addition, the beveled or curved surfaces 1652 may provide less resistance to the intended flow of gas into the exhaust channels 1612.

A coating head with peaks and valleys consistent with the coating head 1650 was tested and was found to reduce the rate of powder generation. While such offsets are known for other purposes, it was discovered that using offsets in coating heads as discussed herein was surprisingly effective at reducing the rate of powder generation.

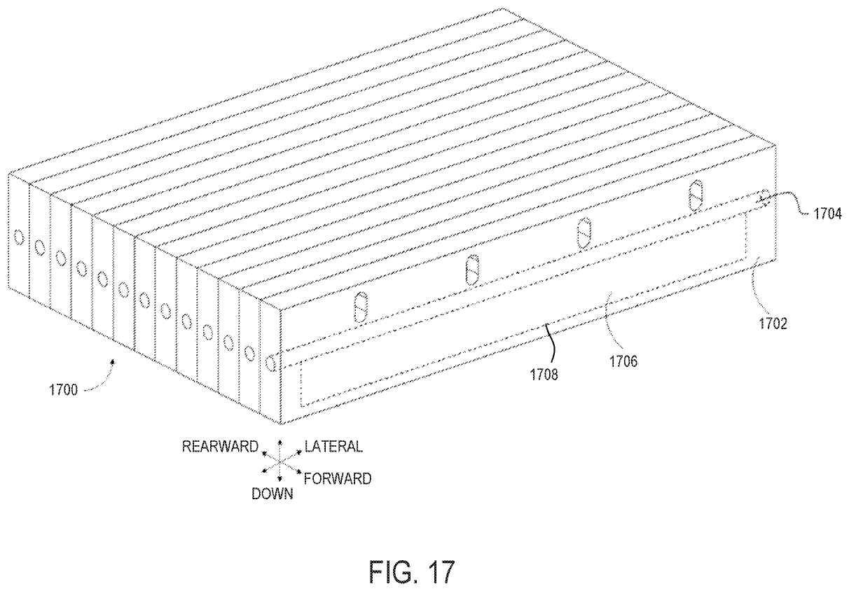

With reference to FIG. 17, for greater context and clarity, an example coating head 1700 is shown. The coating head 1700 may embody any of the features and aspects discussed with respect to the coating heads described elsewhere herein. The coating head 1700 includes a body 1702 (which may be modular) in which channels are provided. A channel may include a first portion 1704, which conveys gas laterally through the body 1702, and a second portion 1706 which conveys gas to/from the substrate (e.g., up/down in the figure) and terminates at a slit 1708 adjacent the substrate (not shown). The cross sections shown in the other figures are generally arranged such that the viewer is looking in the lateral direction indicated in FIG. 17.

In addition, it should be noted that a coating head, as discussed herein, may be made of any suitable material, such as plastic or metal. A plastic coating head may be manufactured by 3D printing using a suitable resin. Advantages attributed to a plastic coating head may also be realized with coating head made of a suitable metal or other material.

In view of the above, it should be apparent that the techniques disclosed herein are useful for powder mitigation and exhaust management for thin film deposition. SALD, an open-air vapor-phase deposition technology, which typically uses a coating head with a variety of gas channels to deliver chemical precursors, shielding gas(es), and/or exhaust channels to remove reaction products, often generates powder that causes issues such fluid system blockage and poor coating properties due to challenges with proper gas isolation and powder mitigation. The techniques disclosed herein may be used to purge airborne particulates from the substrate surface undergoing the SALD process. The techniques may be used to treat and clean a substrate surface for improved coating properties. Furthermore, the techniques provide a controlled methodology to remove excess precursor chemical gas(es), unclog lines, and improve process reliability and uptime.

The terminology used herein is for the purpose of describing specific embodiments only and is not intended to be limiting of the system or disclosure. As used herein, the term “and/or” includes any and all combinations of one or more of the associated listed items. As used herein, the singular forms “a,” “an,” and “the” are intended to include the plural forms as well as the singular forms, unless the context clearly indicates otherwise. It will be further understood that the terms “comprise(s)” and/or “comprising,” when used in this specification, specify the presence of stated features, steps, operations, elements, and/or components, but do not preclude the presence or addition of one or more other features, steps, operations, elements, components, and/or groups thereof.

It should be recognized that features and aspects of the various examples provided above can be combined into further examples that also fall within the scope of the present disclosure. In addition, the figures are not to scale and may have size and shape exaggerated for illustrative purposes.

1. A spatial atomic layer deposition (SALD) system comprising:
a coating head including:
a precursor gas channel configured to provide a precursor gas to a substrate;
a reactant gas channel positioned forward of the precursor gas channel, the reactant gas channel configured to provide a reactant gas to the substrate; and
a sequence of inert gas channels positioned with respect to the precursor gas channel and the reactant gas channel, each inert gas channel configured to provide an inert gas to the substrate to purge unwanted material from the substrate.

2. The SALD system of claim 1, wherein the sequence of inert gas channels is positioned forward or rearward of the reactant gas channel and the precursor gas channel.

3. The SALD system of claim 1, wherein the sequence of inert gas channels is positioned between the reactant gas channel and the precursor gas channel.

4. The SALD system of claim 1, further comprising:
a body in which the precursor gas channel and the reactant gas channel are provided; and
a module in which the sequence of inert gas channels is provided;
wherein the module is removably attachable to the body.

5. The SALD system of claim 1, further comprising, attached to the coating head, a surface treatment apparatus, a particulate monitoring device, an ultrasonic vibrator, a heater, a dehumidifier, a static charge generator, or a combination of such.

6. The SALD system of claim 1, wherein the coating head further comprises a surface treatment at surface of the body of the coating head adjacent the substrate.

7. The SALD system of claim 6, wherein the surface treatment comprises a layer of octadecyl phosphonic acid (ODPA).

8. The SALD system of claim 1, further comprising:
a first exhaust flow path connected to an exhaust channel of the coating head adjacent the precursor gas channel; and
a second exhaust flow path connected to another exhaust channel of the coating head adjacent the reactant gas channel.

9. The SALD system of claim 8, further comprising a pressure gauge positioned at the first exhaust flow path or the second exhaust flow path, the pressure gauge configured to detect a blockage in the first exhaust flow path or the second exhaust flow path.

10. The SALD system of claim 8, further comprising:
a pump positioned at the first exhaust flow path or the second exhaust flow path; and
a flow speed controller connected to the pump;
wherein the pump and flow speed controller are configured to increase a flow rate of exhaust through the first exhaust flow path or the second exhaust flow path to clear a blockage.

11. The SALD system of claim 1, further comprising an environmental control chamber in which the coating head is positioned, wherein the environmental control chamber is configured to control temperature, pressure, and humidity of a local environment around the coating head.

12. The SALD system of claim 1, wherein an end slit of the precursor gas channel or the reactant gas channel is offset from an end slit of an inert gas channel in a direction away from the substrate.

13. A spatial atomic layer deposition (SALD) system comprising:
a coating head including:
a precursor gas channel configured to provide a precursor gas to a substrate;
a reactant gas channel positioned forward of the precursor gas channel, the reactant gas channel configured to provide a reactant gas to the substrate; and
a sequence of exhaust channels positioned with respect to the precursor gas channel and the reactant gas channel, each exhaust channel configured to withdraw unwanted material from a vicinity of the substrate.

14. The SALD system of claim 13, wherein the sequence of inert gas channels is positioned forward or rearward of the reactant gas channel and the precursor gas channel.

15. The SALD system of claim 13, further comprising:
a body in which the precursor gas channel and the reactant gas channel are provided; and
a module in which the sequence of exhaust channels is provided;
wherein the module is removably attachable to the body.

16. The SALD system of claim 13, further comprising, attached to the coating head, a surface treatment apparatus, a particulate monitoring device, an ultrasonic vibrator, a heater, a dehumidifier, a static charge generator, or a combination of such.

17. The SALD system of claim 13, wherein the coating head further comprises a surface treatment at surface of the body of the coating head adjacent the substrate.

18. The SALD system of claim 17, wherein the surface treatment comprises a layer of octadecyl phosphonic acid (ODPA).

19. The SALD system of claim 13, further comprising:
a first exhaust flow path connected to an exhaust channel of the coating head adjacent the precursor gas channel; and
a second exhaust flow path connected to another exhaust channel of the coating head adjacent the reactant gas channel.

20. The SALD system of claim 19, further comprising a pressure gauge positioned at the first exhaust flow path or the second exhaust flow path, the pressure gauge configured to detect a blockage in the first exhaust flow path or the second exhaust flow path.

21. The SALD system of claim 19, further comprising:
a pump positioned at the first exhaust flow path or the second exhaust flow path; and
a flow speed controller connected to the pump;
wherein the pump and flow speed controller are configured to increase a flow rate of exhaust through the first exhaust flow path or the second exhaust flow path to clear a blockage.

22. The SALD system of claim 13, further comprising an environmental control chamber in which the coating head is positioned, wherein the environmental control chamber is configured to control temperature, pressure, and humidity of a local environment around the coating head.

23. The SALD system of claim 13, wherein an end slit of the precursor gas channel, the reactant gas channel, or an exhaust channel is offset from an end slit of an inert gas channel in a direction away from the substrate.

24. A spatial atomic layer deposition (SALD) system comprising:
a coating head including:
a precursor gas channel configured to provide a precursor gas to a substrate;
a reactant gas channel positioned forward of the precursor gas channel, the reactant gas channel configured to provide a reactant gas to the substrate; and
an alternating sequence of inert gas channels and exhaust channels positioned with respect to the precursor gas channel and the reactant gas channel, each inert gas channel configured to provide an inert gas to the substrate to purge unwanted material from the substrate, each exhaust channel configured to withdraw unwanted material from a vicinity of the substrate.

25. The SALD system of claim 24, further comprising:
a body in which the precursor gas channel and the reactant gas channel are provided; and
a module in which the alternating sequence of inert gas channels and exhaust channels is provided;
wherein the module is removably attachable to the body.

26. The SALD system of claim 24, further comprising, attached to the coating head, a surface treatment apparatus, a particulate monitoring device, an ultrasonic vibrator, a heater, a dehumidifier, a static charge generator, or a combination of such.

27. The SALD system of claim 24, wherein the coating head further comprises a surface treatment at surface of the body of the coating head adjacent the substrate.

28. The SALD system of claim 27, wherein the surface treatment comprises a layer of octadecyl phosphonic acid (ODPA).

29. The SALD system of claim 24, further comprising:
a first exhaust flow path connected to an exhaust channel of the coating head adjacent the precursor gas channel; and
a second exhaust flow path connected to another exhaust channel of the coating head adjacent the reactant gas channel.

30. The SALD system of claim 29, further comprising a pressure gauge positioned at the first exhaust flow path or the second exhaust flow path, the pressure gauge configured to detect a blockage in the first exhaust flow path or the second exhaust flow path.

31. The SALD system of claim 29, further comprising:
a pump positioned at the first exhaust flow path or the second exhaust flow path; and
a flow speed controller connected to the pump;
wherein the pump and flow speed controller are configured to increase a flow rate of exhaust through the first exhaust flow path or the second exhaust flow path to clear a blockage.

32. The SALD system of claim 24, further comprising an environmental control chamber in which the coating head is positioned, wherein the environmental control chamber is configured to control temperature, pressure, and humidity of a local environment around the coating head.

33. The SALD system of claim 24, wherein an end slit of the precursor gas channel, the reactant gas channel, or an exhaust channel is offset from an end slit of an inert gas channel in a direction away from the substrate.
